(19) United States
(12) Patent Application Publication
(10) Pub. No.: US 2010/0142177 A1
(43) Pub. Date: Jun. 10, 2010

(54) PLASMA DISPLAY APPARATUS

(76) Inventors: Ji-Eun Lee, Suwon-si (KR); Hui-Yun Hwang, Suwon-Si (KR)

Correspondence Address: CHRISTIE, PARKER & HALE, LLP, PO BOX 7068, PASADENA, CA, 91109-7068, US

(21) Appl. No.: 12/628,807

(22) Filed: Dec. 1, 2009

(30) Foreign Application Priority Data
Dec. 4, 2008 (KR) 10-2008-0122377

(51) Int. Cl. H05K 7/00

(52) U.S. Cl. 361/829

(57) ABSTRACT

A display apparatus includes a display panel and a chassis base on the display panel, wherein at least a portion of a periphery of the display panel contact the chassis base. An area of the chassis base may be equal to or larger than an area of the display panel.

### CROSS-REFERENCE TO RELATED APPLICATION

This application claims priority to and the benefit of Korean Patent Application No. 10-2008-0122377, filed on Dec. 4, 2008, in the Korean Intellectual Property Office, the entire content of which is incorporated herein by reference.

### BACKGROUND OF THE INVENTION

1. Field of the Invention

An aspect of the present invention relates to a plasma display apparatus.

2. Description of the Related Art

A plasma display apparatus is a flat panel display (FPD) in which gases such as neon and argon or neon and xenon are injected into a sealed space between two pieces of glass and a voltage is applied to emit light and to display an image created by the emitted light.

The plasma display apparatus typically includes a plasma display panel (PDP), a driving circuit board on which an electro-electronic circuit for driving the PDP is mounted, and a chassis base for fixing the PDP and the driving circuit board to each other.

The substrates of the PDP are primarily made of glass. Therefore, the PDP is easily fractured when being manufactured, transported, and stored.

The PDP is first attached to the chassis base after being manufactured in order to assemble a display apparatus. The chassis base is a firm or rigid member that supports the PDP and is made of metal or a composite material.

However, in order to make the plasma display apparatus more lightweight and low-priced, the thickness of the PDP has been gradually reduced. Therefore, during processes of manufacturing the plasma display apparatus, the amount of damage caused to the PDP has increased.

In particular, since the conventional chassis base is manufactured so that the frame of the PDP does not contact the chassis base, during the manufacturing processes when a worker holds one side of the PDP together with the chassis base, one end of the PDP may be easily broken. Furthermore, since the one end of the PDP does not contact the chassis base, the PDP may be easily broken by external vibration or impact.

### SUMMARY OF THE INVENTION

Accordingly, in an embodiment of the present invention, a plasma display apparatus is provided including a chassis base structure capable of preventing or reducing the likelihood that a frame or edge portion of a plasma display panel (PDP) will be easily damaged by external force, vibration, and impact during manufacturing.

In one embodiment, a display apparatus includes a display panel and a chassis base on the display panel, wherein at least a portion of the display panel contacts the chassis base. An area of the chassis base may be equal to or larger than an area of the display panel.

In one embodiment, the chassis base includes a bent part extending adjacent a first edge of the chassis base, wherein the bent part defines a through groove. Further, an edge of the bent part may contact an edge of the display panel. In various embodiments, the bent part has a trapezoidal recess, a square recess, a triangular recess, or a semi-circular recess defining the through groove.

In one embodiment, the chassis base further includes a sub-chassis attached to the chassis base, a height of the bent part being substantially equal to a height of the sub-chassis. The chassis base may also include a supplementary bent part on a second edge of the chassis base, wherein the supplementary bent part is an integral portion of the chassis base bent in a direction away from the display panel.

In one embodiment, the display panel is a plasma display panel.

### BRIEF DESCRIPTION OF THE DRAWINGS

The accompanying drawings, together with the specification, illustrate embodiments of the present invention, and, together with the description, serve to explain the principles of the present invention.

FIG. 1 is a perspective view illustrating a PDP and a chassis base for a plasma display apparatus according to one embodiment of the present invention;

FIG. 2A is a top view illustrating the PDP and the chassis base of FIG. 1;

FIG. 2B is a sectional view taken along line I-I′ of the PDP and the chassis base of FIG. 1;

FIGS. 3A, 3B and 3C are partial perspective views illustrating other embodiments of chassis bases for the plasma display apparatus according to one embodiment of the present invention; and

FIG. 4 is a partial perspective view illustrating still another chassis base for the plasma display apparatus according to one embodiment of the present invention.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on another element or be indirectly on another element with one or more intervening elements interposed therebetween. Also, when an element is referred to as being “coupled to” another element, it can be directly coupled to another element or be indirectly coupled to another element with one or more intervening elements interposed therebetween. Hereinafter, like reference numerals refer to like elements.

Embodiments of the present invention will be described in detail with reference to the accompanying drawings.

The present invention now will be described more fully with reference to the accompanying drawings, in which exemplary embodiments of the invention are shown. These embodiments are provided so that this disclosure will be thorough and complete, and will fully convey the concept of the invention to those skilled in the art.

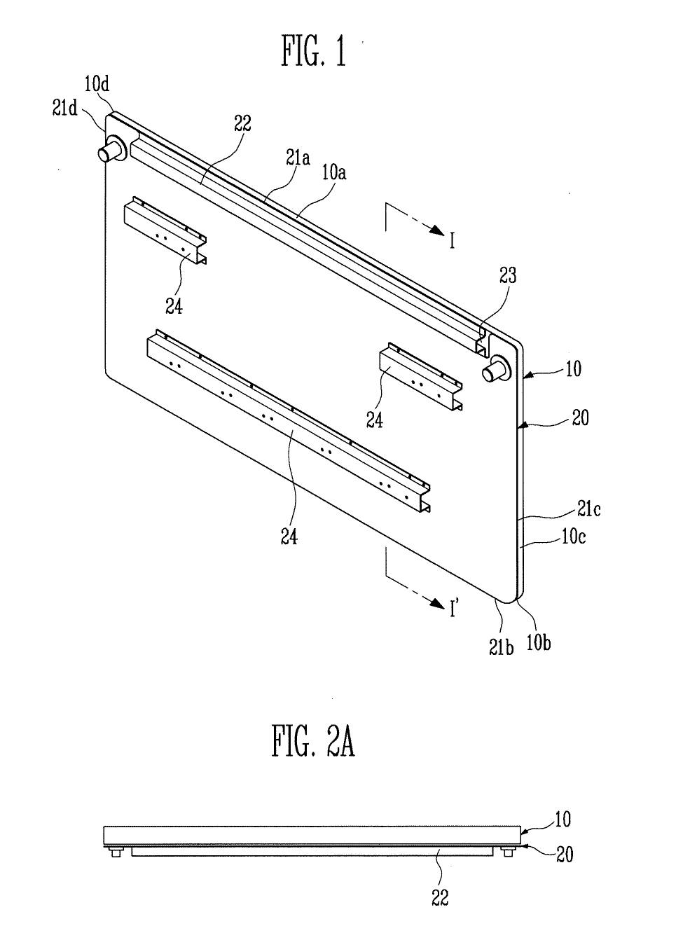

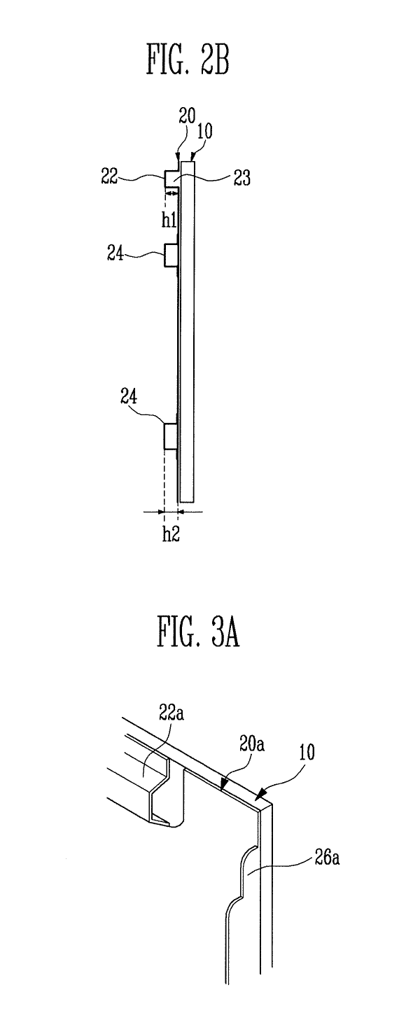

FIG. 1 is a perspective view illustrating a plasma display panel (PDP) and a chassis base for a plasma display apparatus according to one embodiment of the present invention. FIG. 2A is a top view illustrating the PDP and the chassis base of FIG. 1. FIG. 2B is a sectional view taken along the line I-I′ of the PDP and the chassis base of FIG. 1.

Referring to FIGS. 1, 2A and 2B, the plasma display apparatus includes a PDP 10 and a chassis base 20.

The PDP 10 (hereinafter, also referred to as a panel) includes a pair of substrates arranged to face each other, barrier ribs arranged between the pair of substrates to partition off a discharge space, a group of electrodes arranged in the substrates so that discharge is generated by the discharge space, and red, green, and blue phosphors arranged in the discharge space to emit light by discharge.

The chassis base 20 is provided on a surface of the panel 10 so that the heat transmitted by the panel 10 is conducted towards the chassis base.

The chassis base 20 can be made of an aluminum plate having a thickness of between about 1.5 to 2.5 mm. In addition, through holes or concave-convex portions having various sizes can be provided on the chassis base 20. The through holes or the concave-convex portions can be used for installing other components such as a driving circuit board on one surface of the chassis base 20.

In the chassis base 20 according to the present embodiment, in order to protect the edge portion of the panel 10 that is most easily damaged, in particular, the upper end of a surface on which an image is displayed, the frame or the entire side end of the panel 10 including the upper end contacts the frame or the entire side end of the chassis base 20. In other words, an edge of the panel 10 is substantially aligned with an edge of the chassis base 20.

Therefore, the chassis base 20 is made to have substantially the same area as the area of the panel 10. That is, when the surface on which the screen is to be displayed is viewed from the back of the panel 10, the panel 10 includes a first side surface or edge 10a extending along the upper part of the panel 10, a second side surface or edge 10b extending along the lower part of the panel 10, a third side surface or edge 10c extending along the right of the panel 10, and a fourth side surface or edge 10d extending along the left of the panel 10. The chassis base 20 includes a first side surface or edge 21a extending along the upper part of the chassis base, a second side surface or edge 21b extending along the lower part of the chassis base, a third side surface or edge 21c extending along the right of the chassis base, and a fourth side surface or edge 21d extending along the left of the chassis base that corresponds respectively to the first side surface 10a, the second side surface 10b, the third side surface 10c, and the fourth side surface 10d. The pairs of corresponding side surfaces are positioned on the same plane.

Furthermore, the chassis base 20 includes a bent part 22 extending along the upper end of the chassis base and at least partially defining the first side surface 21a. The bent part 22 is configured to define a through groove 23 defined on three sides by the bent part and on one side by a surface of the panel 10. More specifically as shown in FIG. 2B, the bent part 22 has a configuration in which a generally C-shaped or U-shaped portion defining the through groove 23 has a flange portion on both sides that contacts the panel 10.

The bent part 22 prevents or reduces the likelihood that the upper part of the panel 10 will be fractured and can be useful for transporting and storing a plurality of chassis bases 20. That is, when a chassis base 20 has the bent part 22 including a square recess, a bent part 22 of a first chassis base 20 can be inserted into the bent part of an adjacent chassis base when a plurality of chassis bases are stacked because of the bent part 22 having a ductility and elasticity, allowing a large number of chassis bases to be easily transported and stored.

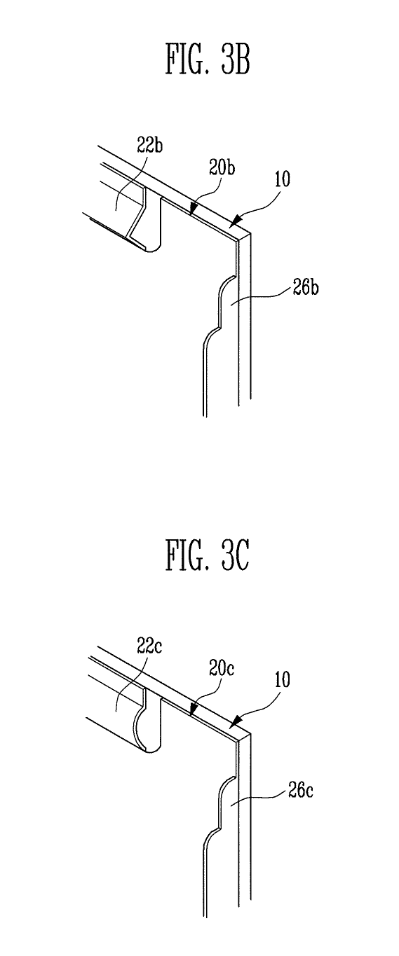

In addition to the bent part 22 with the square recess, as illustrated in FIGS. 3A, 3B, and 3C, other bent parts 22a, 22b, and 22c including trapezoidal, triangular, and semi-circular recesses may be provided. As such, other chassis bases 20a, 20b, and 20c including the bent parts 22a, 22b, and 22c can be provided.

The chassis base 20 can include a sub chassis 24 as a reinforcing member for preventing or reducing the likelihood that the chassis base 20 will be bent. Alternatively or in addition, the chassis base 20 can include a supporting frame for supporting other parts or components provided on one surface of the chassis base. As illustrated in FIG. 1, the sub chassis 24 is an additional member bent in the form of a drainage channel and is attached to one surface of the plate-shaped chassis base 20. The sub chassis 24 protrudes from the chassis base 20 by a height. In one embodiment, as illustrated in FIG. 2B, the protrusion height h2 of the sub-chassis is substantially equal to the protrusion height h1 of the through groove 23 defined by the above-described bent part 22. In this case, the contact surface between the panel 10 and a case provided outside of the chassis base 20 is made substantially uniform so that the convenience of assembly can be improved.

In addition, the above-described sub chassis 24 can also be provided at the lower end or edge of the chassis base 20. In this case, the sub chassis 24 provided at the lower end can be used as a member for facilitating the coupling of a holder or legs to the lower part of the chassis base 20.

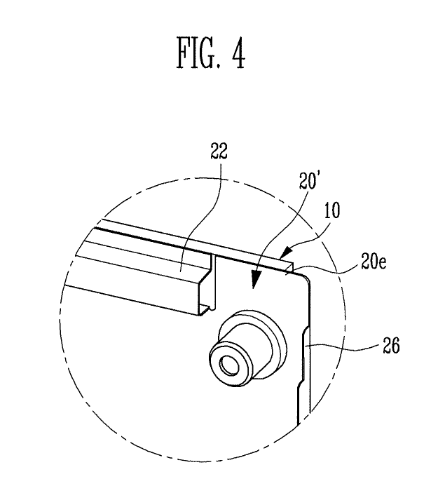

FIG. 4 is a partial perspective view illustrating another chassis base provided in the plasma display apparatus according to one embodiment of the present invention.

Referring to FIG. 4, a chassis base 20′ according to the present embodiment is made larger than the panel 10. That is, the chassis base 20′ protrudes past the panel 10. In addition, the corner 20e of the chassis base 20′ protrudes past a corresponding corner of the panel 10. When the chassis base 20′ is larger than the panel 10, it is possible to effectively prevent or reduce the edge portion of the panel 10 from being fractured.

In addition, the chassis base 20′ includes a supplementary bent part 26 bent at about a right angle in a direction away from the panel 10 and extending along the edge 20e of the panel.

The above-described supplementary bent part may be integral with the chassis base 20′ and may be formed by bending a portion of the chassis base. In embodiments as shown in FIGS. 3A-3C, chassis bases 20a, 20b, and 20c may include supplementary bent parts 26a, 26b, and 6c, respectively, that are substantially aligned with an edge of the panel 10 to prevent or significantly reduce the likelihood of the edge portion of the side surface of the panel 10 from being broken and to improve the strength of the side surface of the chassis base 20′.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A plasma display apparatus, comprising:
a plasma display panel; and
a chassis base on the plasma display panel, wherein at least a portion of the periphery of the plasma display panel contacts the chassis base.

2. The plasma display apparatus as claimed in claim 1, wherein the chassis base comprises a bent part extending adjacent a first edge of the chassis base.

3. The plasma display apparatus as claimed in claim 2, wherein the bent part defines a through groove.

4. The plasma display apparatus as claimed in claim 3, wherein an edge of the bent part contacts a portion of the periphery of the plasma display panel.

5. The plasma display apparatus as claimed in claim 4, wherein the bent part has a trapezoidal recess, a square recess, a triangular recess, or a semi-circular recess defining the through groove.

6. The plasma display apparatus as claimed in claim 2, wherein the chassis base comprises a sub-chassis.

7. The plasma display apparatus as claimed in claim 6, wherein a height of the bent part is substantially equal to a height of the sub-chassis.

8. The plasma display apparatus as claimed in claim 2, the chassis base further comprising a supplementary bent part on a second edge of the chassis base.

9. The plasma display apparatus as claimed in claim 8, wherein the supplementary bent part is an integral portion of the chassis base bent in a direction away from the plasma display panel.

10. The plasma display apparatus as claimed in claim 1, wherein an area of the chassis base is equal to or larger than an area of the plasma display panel.
